(19) United States
(12) Patent Application Publication
(10) Pub. No.: US 2024/0237767 A1
(43) Pub. Date: Jul. 18, 2024

(54) GLOVE, ELECTRICAL ASSEMBLY AS WELL AS WEARABLE DEVICE

(71) Applicant: Workaround GmbH, München (DE)

(72) Inventors: Michael KETTNER, München (DE); Simon ARMBRUSTER, München (DE); Omar ALAASER, München (DE); Danijel JURIC, München (DE); David STILWELL, München (DE); Hans HOCHKEPPEL, München (DE)

(21) Appl. No.: 18/411,278

(22) Filed: Jan. 12, 2024

(30) Foreign Application Priority Data
Jan. 13, 2023 (DE) 10 2023 100 787.4

(51) Int. Cl. A41D 19/00; H01H 13/14; H03K 17/96

(52) U.S. Cl. CPC A41D 19/0024; H01H 13/14; H03K 17/96

(57) ABSTRACT

A glove has a dorsal section and a fastening section. The fastening section is designed to fasten the dorsal section onto a user's hand. The dorsal section includes a trigger opening and a holder opening, and the dorsal section is designed in such a way that a trigger of an electrical assembly is inserted into the trigger opening and can be held there by the dorsal section and/or a holder of the electrical assembly is inserted into the holder opening and can be held there by the dorsal section. Moreover, a wearable device and an electrical assembly are shown.

### FIELD OF THE DISCLOSURE

The disclosure relates to a glove, an electrical assembly as well as a wearable device comprising a glove and an electrical assembly.

### BACKGROUND

Gloves with electrical triggers are known and are used, for example, in combination with one or more electronic modules. These electronic modules usually comprise sensors and can also be attached to the glove, resulting in a wearable device termed a “wearable”.

For example, the electronic module is a barcode scanner and the trigger is used to trigger a scanning process. The trigger can also be used for other purposes, such as counting processes or operating further units of the wearable.

To this end, the electrical trigger is connected electrically to the electronic module or a holder for this purpose by means of a signal line.

Typically, the trigger, the holder for the electronic module and the signal line in the form of an electrical conductor are integrated into the glove or are permanently connected to the glove.

However, the production costs of the glove increase as a result and the electrics must be disposed of when the glove is worn out, even if the electrics per se would still be intact.

### SUMMARY

Thus, there is provided a glove, an electrical assembly as well as a wearable device that is economical to produce, however, simultaneously guarantees a high level of comfort when being put on or taken off.

There is provided a glove, in particular a work glove, comprising a dorsal section and a fastening section. The fastening section is designed to fasten the dorsal section onto a user's hand. The dorsal section has a trigger opening and a holder opening. The dorsal section is designed in such a way that a trigger of an electrical assembly can be inserted into the trigger opening and can be held there by the dorsal section and/or a holder of the electrical assembly can be inserted into the holder opening and can be held there by the dorsal section.

As the trigger opening and/or holder opening are designed in such a way that they can hold the trigger and/or the holder, the glove together with the electrical assembly can be put on like a glove with integrated components. It is therefore not necessary to integrate the trigger and the holder into the glove. At the same time, however, the glove is considerably more economical to produce.

In particular, the trigger opening and the holder opening are separate from each other.

For example, the trigger opening and the holder opening extend completely through the palm section, thus from the upper side to the underside.

Within the scope of this disclosure, the side of the dorsal section or the fastening section facing away from the user's hand in the worn state is termed the upper side and the side facing the user's hand is termed the underside. The vertical direction is understood to be the direction from the underside to the upper side.

“Held” means within the scope of this disclosure, for example, that the inserted trigger or holder is supported by the glove and/or that the trigger or the holder is permanently fixed in the vertical direction not relative to the glove.

The trigger opening can be provided on the thumb-side of the holder opening, in particular in the region of the dorsal section that rests on the index finger.

In an embodiment, the dorsal section is designed in such a way that the trigger and/or holder can be inserted into the trigger opening and/or the holder opening from an underside of the dorsal section. In this way, the electrical assembly is attached reliably by means of the glove.

To reduce the production costs of the glove further, the dorsal section, in particular the entire glove, can be free of conductors and/or rigid components.

Conductors are, for example, conductor paths, cables or conducting threads. Rigid components are, for example, components made of metal, wood, a thermoplastic or a thermoset. In particular, hook-and-loop fastenings or strips (both hook-side and loop-side strips) are not rigid components within the meaning of this disclosure.

In an embodiment, the dorsal section is designed flexibly, in particular wherein the dorsal section comprises at least one material layer made of a stretchable material, in particular neoprene, imitation leather, synthetic leather, a microfibre material, a mesh material and/or a spacer fabric, thereby increasing the wearing comfort of the glove.

The dorsal section can be made out of a stretchable material layer or several stretchable material layers made of the same or different materials.

In an embodiment, the trigger opening and/or the holder opening are limited by the edge of the dorsal section, wherein at least a fastening means for the trigger and/or for the holder, in particular a part of a hook-and-loop fastener and/or an elastic lip, is located on the edge. By means of the fastening means, it is possible to ensure extremely reliably that the trigger and the holder are held in the corresponding opening.

For example, the lip extends from the edge into the corresponding opening.

The part of hook-and-loop fastener is, for example, installed on the underside of the dorsal section.

In an embodiment, the fastening section is a palm section, in particular which is formed as a single piece with the dorsal section. In this way, the glove can be put on extremely simply.

For example, a thumb opening is formed between the palm section and the dorsal section.

In an embodiment, the fastening section is a strap section, in particular which extends with an end from the dorsal section, in particular a region around the trigger opening, and is fastened detachably with its other end on the dorsal section. In this way, the same glove can be fastened reliably onto hands extremely different in size.

There is further provided a wearable device comprising a glove as previously described and an electrical assembly. The electrical assembly comprises a trigger and a holder, which are connected electrically to each other by means of an electrical conductor, wherein the trigger and/or holder are inserted into the trigger opening and/or the holder opening and are held by the dorsal section.

The features and advantages described for the glove equally apply to the device and vice versa.

In particular, the contour of the trigger opening and/or the holder opening corresponds to the outer contour of the trigger and/or the holder in top view.

The glove and the electrical assembly are parts that are separate from each other.

For example, the trigger and/or holder extend from the underside of the dorsal section through the trigger opening and/or holder opening and/or project over the upper side of the dorsal section, thereby facilitating ease of use.

In an embodiment, the trigger and/or holder have a size in the transverse direction and/or longitudinal direction, wherein the trigger and/or the holder are larger in the longitudinal direction and/or in the transverse direction than the trigger opening and/or holder opening in the corresponding direction. In this way, an interference fit is realised, through which the trigger and/or the holder are held in the corresponding opening.

The longitudinal and transverse directions are, in particular, perpendicular to the vertical direction.

For example, the electrical assembly comprises a base layer, on which the trigger and/or the holder are attached, in particular wherein the base layer adjoins the underside of the dorsal section. By means of the base layer, the electrical assembly can be simply handled.

The base layer comprises at least one fastening means, in particular a part of a hook-and-loop fastener, through which the trigger and/or the holder are held even more reliably.

The part of the hook-and-loop fastener is located around the trigger and/or the holder and/or on the same side of the base layer as the trigger and the holder.

In an embodiment, the electrical assembly has a connecting part that extends from the holder to the trigger and defines the spacing between the trigger and the holder, thereby simplifying the insertion of the electrical assembly onto the glove.

The defined spacing relates to a state when the electrical assembly is spread out on a flat surface. The base layer can also define the relative position of the trigger to the holder.

The electrical conductor is attached, in particular, to the connecting part.

To be capable of using the electrical assembly in different-sized gloves, the electrical assembly can have a connecting part that extends from the holder to the trigger and whose length is changeable in such a way that the spacing between the trigger and the holder is changeable.

In an embodiment, the wearable device comprises an electronic module that is inserted into the holder, in particular wherein the electronic module comprises a camera, a code reader, for example for optical codes or RFID tags, and/or a display for displaying instructions to the user, which are triggerable by actuating the trigger, thereby making it possible to obtain data by means of the wearable device.

To ensure reliable contacting, the holder comprises at least one electrical contact that is connected electrically to the trigger by means of the conductor, in particular wherein at least one mating contact of the electronic module contacts the electrical contact of the holder physically.

Moreover, an electrical assembly is provided for a wearable device, in particular as previously described. The electrical assembly comprises a trigger and a holder, which are connected electrically to each other by means of an electrical conductor.

The features and advantages described for the wearable device and the glove equally apply to the electrical assembly and vice versa.

For example, the electrical assembly comprises a base layer, on which the trigger and/or the holder are attached, in particular wherein the holder protrudes from the upper side of the base layer.

In an embodiment, the electrical assembly comprises a connecting part that extends from the holder to the trigger and whose length is changeable in such a way that the spacing between the trigger and the holder is changeable. As a result, the electrical assembly can be used in the different-sized gloves and with different spacings between the trigger and the holder openings.

### BRIEF DESCRIPTION OF THE DRAWINGS

Additional features and advantages of the disclosure are found in the following description as well as the attached drawings to which reference is made. In the drawings:

FIG. 1 shows a first embodiment of a wearable device according to the disclosure comprising a first embodiment of a glove according to the disclosure in the non-assembled state,

FIG. 2 shows an underside view of the glove according to FIG. 1,

FIG. 3 shows a top view of the wearable device according to FIG. 1 in the assembled state without the electronic module,

FIG. 4 shows a sectional view of the wearable device according to FIG. 1 in the assembled state without the electronic module,

FIG. 5 shows an underside view of the wearable device according to FIG. 1 in the assembled state without the electronic module,

FIG. 6 shows a second embodiment of a wearable device according to the disclosure comprising a second embodiment of a glove according to the disclosure in the non-assembled state,

FIG. 7 shows an electrical assembly of a third embodiment of a device according to the disclosure in top view, and

FIG. 8 shows a fourth embodiment of a wearable sensor device, wherein only the fourth embodiment of the glove according to the disclosure is shown.

### DETAILED DESCRIPTION

Lists having a plurality of alternatives connected by “and/or”, for example “A, B and/or C” are to be understood to disclose an arbitrary combination of the alternatives, i.e. the lists are to be read as “A and/or B and/or C” or as “at least one of A, B or C”. The same holds true for listings with more than three items.

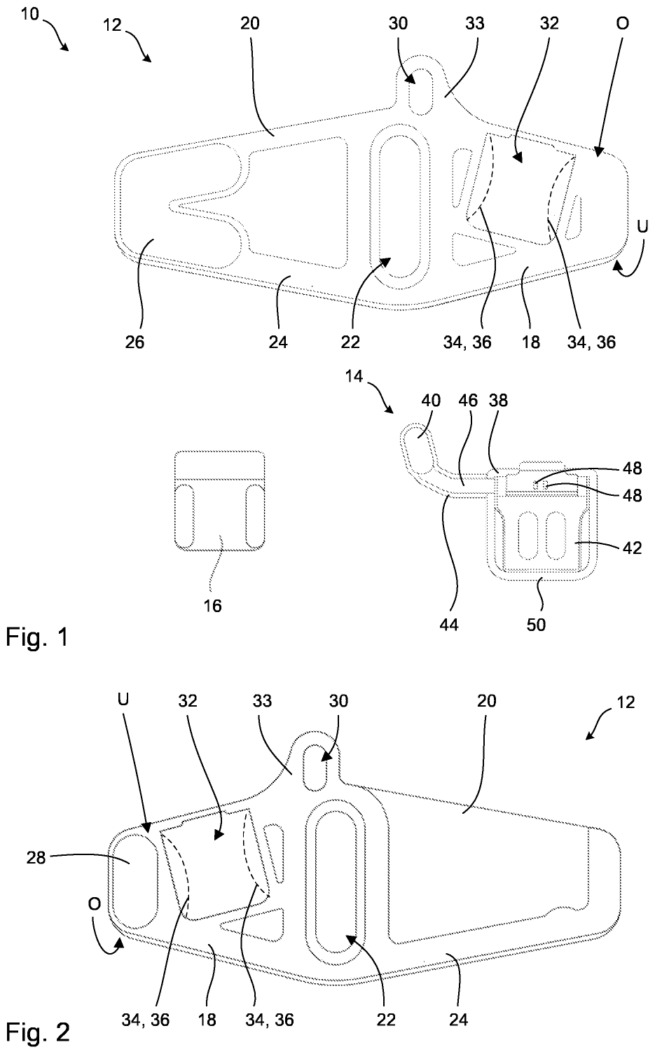

In FIG. 1, a wearable device 10 is shown comprising a glove 12, an electrical assembly 14 and an electronic module 16.

In the situation shown in FIG. 1, the wearable device 10 is not being worn and the glove 12, the electrical assembly 14 and the electronic module 16 are not assembled. The glove 12 is spread out on a flat surface.

The electronic module 16 is, for example, a compact and robust device for industrial applications. In particular, the electronic module 16 comprises a camera, a code reader and/or a display for displaying instructions to the user.

The code reader can be configured, for example, to read optical codes, such as barcodes or 2D codes, or to read RFID tags.

In particular, the electronic module 16 is not a smart device, such as a smartphone.

The glove 12 is for example a work glove, for example for workers on an assembly line or employees in a logistics centre.

The glove 12 of the embodiment shown is not a full glove with complete fingers or the bases of fingers, but rather a glove that only covers the dorsum and the palm of a user's hand, provided it is worn correctly. The glove 12 is thus similar to a fingerless covering or a bandage that only surrounds parts of the hand and does not need to be pulled over the hand, but rather is closed around the hand.

Fingers or the bases of fingers are not provided on the glove 12.

The glove 12 comprises a dorsal section 18 and a fastening section 20.

In the first embodiment shown, the fastening section 20 is a palm section, and the dorsal section 18 and the fastening section 20 are designed as a single piece.

A thumb opening 22 is designed in the glove 12 between the palm section and the dorsal section 18.

If the glove 12 is worn correctly, the fastening section 20, thus the palm section in the first embodiment, is located on the palm of the user's hand and the dorsal section 18 is located on the dorsum of the user's hand and covers this.

The dorsal section 18 largely covers the dorsum of the user's hand.

The dorsal section 18 and the fastening section 20 have an upper side O and an underside U. When the glove 10 is worn correctly, the underside U is that side resting on the hand or on a glove worn underneath by the user. The upper side O is the opposite side, i.e. the side facing away from the user's hand.

The vertical direction is understood to be the direction from the underside U to the upper side O perpendicular to the dorsal section 18.

The dorsal section 18 and the fastening section 20 form parts of a band-like base body 24, that is, for example, elastic.

The band-like base body 24 comprises two short end edges and two long longitudinal edges, wherein the longitudinal edge, which is facing the user's fingers when the glove 12 is worn correctly, is referred to as the finger-side edge. The opposing longitudinal edge is then facing the wrist and is thus termed the wrist-side edge.

The dorsal section 18 is designed flexibly so that it can be adjusted to the user's hand.

The dorsal section 18 is made of, for example, several material layers that are flexible. One or more of the material layers can even be stretchable.

For example, the stretchable material layer is made of neoprene, imitation leather, synthetic leather, a microfibre material, a mesh material and/or a spacer fabric.

The different material layers can be made of the same or different materials.

The dorsal section 18 and the entire glove 12 are designed without any rigid parts, such as reinforcements or supports made of metal, wood, a thermoplastic or a thermoset.

The dorsal section 18 and, in particular, the entire glove 12 are also designed without any conductors permanently fixed, such as integrated, interwoven, sown or adhered cables, conductor paths or conducting threads.

A first fastening element 26 is attached to the dorsal section 18 on the end edge on the underside U, which is indicated by dashed lines in FIG. 1.

Similarly, a second fastening element 28 is attached to the fastening section 20 on the end edge, however to the upper side O, said second fastening element 28 interacts with the first fastening element 26 when the glove 12 is worn correctly so that the glove 12 can be fixed in place on the user's hand. The first and the second fastening elements 26, 28 may form, for example, a part of a hook-and-loop fastening. The components of the hook-and-loop fastening (hook as well as loop parts) are not regarded as rigid components within the scope of this disclosure.

Thus, the dorsal section 18 is fixed in position on the user's hand by means of the fastening section 20.

It is also conceivable that the first fastening element 26 is provided on the upper side O and the second fastening element 28 is provided on the underside U.

Moreover, it is conceivable that a gap or another opening is provided close to one of the end edges, through said gap or opening the opposite end edge and parts of the base body 24 can be pulled. The part of the base body 24 pulled through the gap can then be fastened to the part of the base body 24 not pulled through, for example by means of a hook-and-loop fastener, in order to fasten the glove 12 onto the user's hand.

The dorsal section 18 comprises two openings for the electrical assembly 14 that are separate from each other, namely a trigger opening 30 and a holder opening 32. Both the trigger opening 30 and the holder opening 32 extend completely from the upper side O to the underside U through the dorsal section 18, i.e. through all material layers. This can also be seen in FIG. 2, which shows the glove from below, i.e. a view of the underside U.

The trigger opening 30 is offset from the holder opening 32 in the direction of the user's index finger. For example, the trigger opening 30 is arranged in such a way that it rests on the user's index finger, in particular on the metacarpophalangeal joint of the index finger, in the correctly worn state.

For example, the dorsal section 18 has a tongue 33 that extends more distally than the finger-side edge of the fastening section 20 and/or the finger-side edge of the remaining dorsal section 18.

The trigger opening 30 is located at least in part, in particular completely, on the tongue 33.

Both the trigger opening 30 and the holder opening 32 are limited by a corresponding edge of the dorsal section 18. A fastening means 34 can be provided on the edge.

In the first embodiment, a fastening means 34 is not provided, however, an elastic lip 36 is indicated by dashed lines as a fastening means 34, said lip 36 extending from the edge into the trigger opening 30 and/or holder opening 32.

The electrical assembly 14 comprises a base layer 38, a trigger 40, a holder 42, a connecting part 44 as well as at least one electrical conductor 46.

The holder 42 is used to receive and attach the electronic module 16 and comprises a corresponding receiving space for this.

Two electrical contacts 48 are provided on the holder 42, said contacts 48 being used for the contacting of the electronic module 16. The contacts 48 protrude into the receiving space of the holder 42, into which the electronic module 16 can be inserted.

The electronic module 16 comprises correspondingly implemented mating contacts (not shown) that contact to the contacts 48 physically and electrically, when the electronic module 16 is inserted into the holder 42.

It is also conceivable that the electrical assembly 14 comprises the electronic module 16 that is then attached to the base layer 38 permanently. In this case, the contacts 48 correspond to the contacts of the holder 42 and the mating contacts of the electronic module 16.

The holder 42 is attached to the upper side of the base layer 38. The base layer 38 also comprises an abutment section 50 which extends around the holder 42.

The trigger 40 is, for example, a mechanical push button that is attached to the upper side of the base layer 38. An abutment section 50 of the base layer 38 can also be designed around the trigger 40.

The trigger 40 is connected electrically to the holder 42, in particular the contacts 48 of the holder 42, by means of the conductor 46, which is designed as a flex PCB cable in the shown embodiment.

The electrical conductor 46 is also attached to the base layer 38 and runs through the connecting part 44.

The connecting part 44 extends from the holder 42 to the trigger 40.

It is conceivable that the connecting part 44 is only made of the electrical conductor 46.

The base layer 38 is a material layer, for example made of a non-stretchable material, such as nylon. It can be a 210 dernier, tearproof nylon.

The material of the base layer 38 is at least less stretchable than the material of the base layer 24.

The spacing between the trigger 40 and the holder 42 is defined by the non-stretchable base layer 38 and/or the connecting part 44. In the shown embodiment, the relative position of the trigger 40 to the holder 42 is also defined by the non-stretchable base layer 38 and/or the connecting part 44. The relative position of the trigger 40 to the holder 42 corresponds to the relative position of the trigger opening 30 to the holder opening 32 in the dorsal section 18.

In the shown embodiment, the trigger 40 has an outer contour that is a rectangular shape with applied semi-circular segments. Such a contour can also be termed a racetrack contour.

The trigger 40 has a size in the longitudinal direction and transverse direction which are both perpendicular to the vertical direction.

The trigger 40 is installed on the upper side of the base layer 38 and protrudes higher over the base layer 38 than the dorsal section 18 is thick in the vertical direction.

The holder 42 has a substantially rectangular outer contour comprising rounded corners and similarly has a size in the longitudinal and transverse directions.

The holder 42 is also attached to the upper side of the base layer 38 and protrudes higher over the upper side than the dorsal section 18 is thick in the vertical direction.

The trigger opening 30 and the holder opening 32 to designed in such a way that they correspond to the outer contours of the trigger 40 and the holder 42.

Thus, the trigger opening 30 also has a rectangular shape with applied semi-circular segments and the holder opening 32 has the shape of a rectangle with rounded corners.

In the first embodiment, however, the size of the trigger opening 30 and the holder opening 32 is smaller in the longitudinal and transverse directions than the size of the trigger 40 and the holder 42 in the corresponding direction.

However, the difference in size between the openings 30, 32 and the trigger 40 and the holder 42 is selected so small that the trigger 40 can be inserted into the trigger opening 30 and the holder 42 into the holder opening 32.

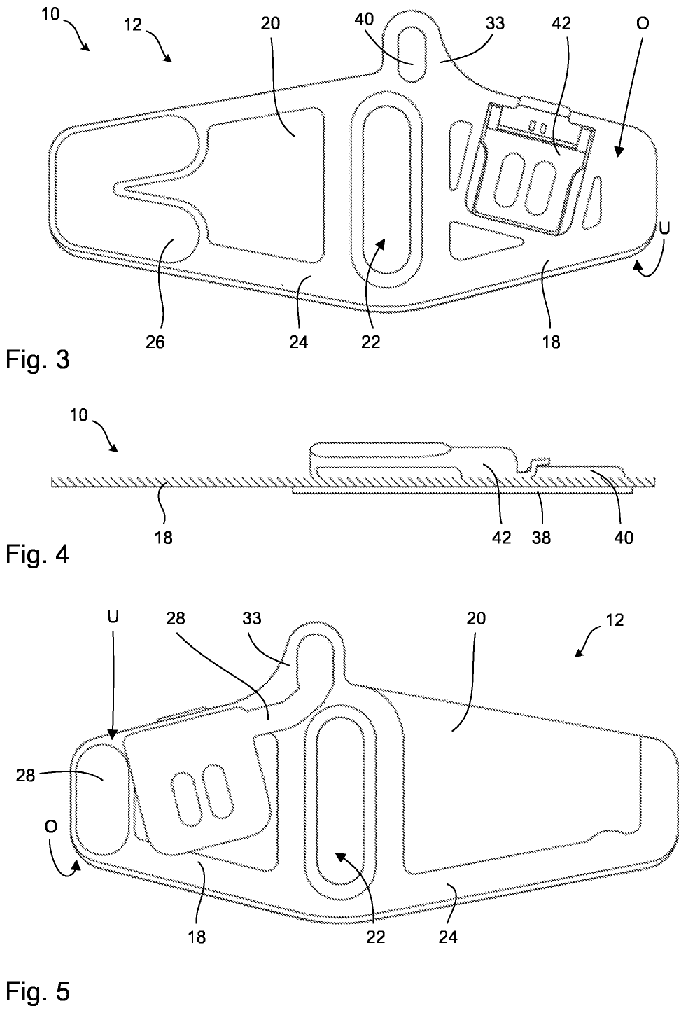

In FIGS. 3 to 5, the electrical assembly 14 is shown in the state assembled with the glove 12 in a top view, a section view and an underside view.

It is clearly evident that the trigger 40 has been inserted into the trigger opening 30 from the underside U of the dorsal section 18 and deployed there.

Similarly, the holder 42 has been inserted through the holder opening 32 from the underside U of the dorsal section 18 and is now deployed in the holder opening 32.

Both the trigger 40 and the holder 42 protrude over the upper side O of the dorsal section 18 owing to their heights, as can be seen in FIG. 4.

As can be seen in FIG. 5, the upper side of the base layer 38 adjoins the underside U of the dorsal section 18. In particular, the connecting part 44 extends completely on the underside U of the dorsal section 18.

Due to the difference in size between the trigger opening 30 and the trigger 40 as well as between the holder opening 32 and the holder 42, an interference fit is realised so that the trigger 40 is held in the trigger opening 30 and the holder 42 is held in the holder opening 32 by the dorsal section 18.

The trigger 40 and the holder 42, in particular the entire electrical assembly 14, are thus held by the dorsal section 18 and by the entire glove 12. This means that, for example, the electrical assembly 14 is also lifted by lifting the glove 12 itself.

A fixation in the vertical direction of the trigger 40 and the holder 42 in relation to the dorsal section 18 and the glove 12 is not achieved by the dorsal section 18. The fixation of the electrical assembly 14, in particular the trigger 40 and the holder 42 in the vertical direction, first occurs in the worn state of the device 10 on a user's hand.

In the worn state, the electrical assembly 14, in particular the trigger 40 and the holder 42, are supported downwards on the user's hand and are held from above by the dorsal section 18.

The dorsal section 18 rests on the abutment section 50 so that the base layer 38, the trigger 40 and the holder 42 cannot fall out or be removed from the upper side O of the dorsal section as the size of the abutment section 50 in the longitudinal and transverse directions is always selected in such a way that it is larger than the corresponding opening 30, 32 in the corresponding direction.

The trigger 40 and the holder 42 with the electronic module 16 are thus fixed in place on the user's hand securely. The user can now actuate the electronic module 16, for example trigger a code reader by actuating the trigger 40.

By using an electrical assembly 14 that is separate from the glove 12, the glove 12 is extremely economical to produce as it can be free of conductors or comparatively expensive components.

Simultaneously, it is possible that the same electrical assembly 14 can be used for different-sized gloves 12. This is possible as the relative position of the trigger opening 30 and the holder opening 32 is always identical in different-sized gloves 12, even though the size of the dorsal section 18 and/or the fastening section 20 varies.

For example, the relative position of the trigger opening 30 in relation to the holder opening 32 is tailored to a medium-sized glove 12, which is then also retained in larger or smaller gloves 12.

As the dorsal section can hold the electrical assembly, putting on and taking off the wearable device 10 is greatly simplified and has the same comfort as putting on a glove with integrated trigger and holder.

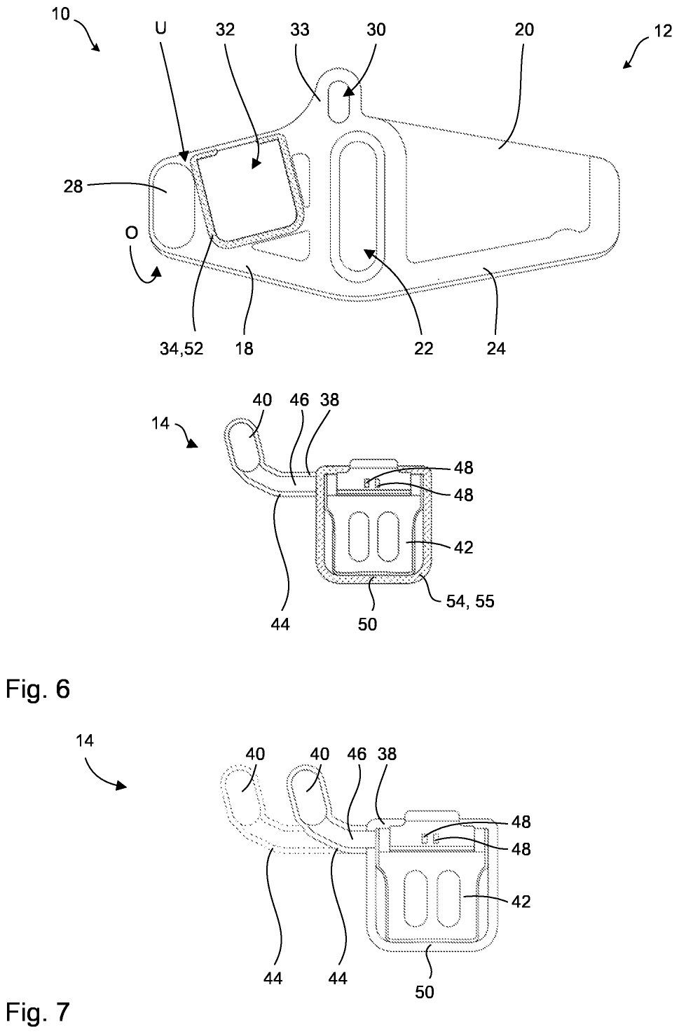

FIGS. 6 to 8 show further embodiments of the disclosure that correspond substantially to the first embodiment so that only the differences are discussed hereinafter. Identical and functionally equivalent parts are provided with the same reference signs.

In FIG. 6, a second embodiment of the wearable device 10 is shown, wherein for simplification the electronic module 16 is not shown.

The glove 12 is shown in an underside view similar to FIG. 2 and the electrical assembly 14 is shown in a top view similar to FIG. 1.

In contrast to the first embodiment, the fastening means 34 in the form of a part of a hook-and-loop fastener 52 is designed on the dorsal section 18 on the edge of the holder opening 32. This part of the hook-and-loop fastener 52 also does not constitute a rigid component within the meaning of this disclosure.

The part of the hook-and-loop fastener 52 extends around the holder opening 32, nearly completely in the shown embodiment.

The part of the hook-and-loop fastener 52 extends on the underside U of the dorsal section 18 and in the region of the dorsal section 18, which corresponds to the abutment section 50 of the base layer 38.

A fastening means 54 in the form of a part of a hook-and-loop fastener 55 is also located on the upper side of the base layer 38. The part of the hook-and-loop fastener 55 extends around the holder 42.

The fastening means 54, here the part of the hook-and-loop fastener 55, is located in the abutment section 50.

In the second embodiment shown, a fastening means 34 or 54 is not provided around the trigger opening 30 or the trigger 40. It is however conceivable that even the edge of the trigger opening 30 and/or the abutment section 50 around the trigger 40 are provided with corresponding hook-and-loop fastener 52, 55.

When the electrical assembly 14 is inserted into the glove 12, the parts of the hook-and-loop fastener 52, 55 connect to each other so that the holder 42 is held in the holder opening 32 by means of the hook-and-loop fastener 52, 55.

In the second embodiment, it is possible to forgo the interference fit of the first embodiment, i.e. the size of the holder opening 32 in the longitudinal and/or transverse directions can be the same or larger than the size of the holder 42 in the corresponding direction.

Irrespective of the holder opening 32, this also applies to the trigger opening 30, even if no fastening means or hook-and-loop fastener 52, 55 is provided on the trigger opening 30 and/or the abutment section 50 on the trigger 40.

In FIG. 7, an electrical assembly 14 is shown according to a third embodiment of the disclosure.

In this third embodiment, the length of the connecting part 44 is changeable. For example, the connecting part 44, i.e. the base layer 38 and/or the electrical conductor 46 in the area of the connecting part 44, has a meander or concertina shape so that the length between the trigger 40 and the holder 42 is changeable.

Thus, the spacing between the trigger 40 and the holder 42 can be changed to adapt the spacing and the relative position of the trigger 40 in relation to the holder 42 to the relative position of the trigger opening 30 in relation to the holder opening 32.

As a result, it is possible that the relative position of the trigger opening 30 in relation to the holder opening 32 can also be different in different-sized gloves 12. Thus, the trigger 40 and the holder 42 (and thus the electronic module 16) can be positioned relative to each other according to the size of the hand in order to always ensure optimal wearing comfort.

Through the changeability of the connecting part 44, it is still possible to only provide one electrical assembly 14 for different sizes of glove 12.

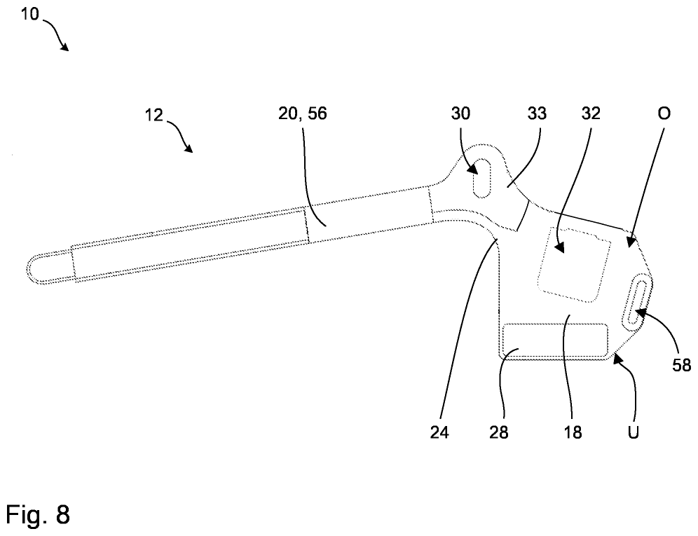

In FIG. 8, a fourth embodiment of the wearable device 10 is shown, namely a fourth embodiment of a glove 12 in top view.

In this fourth embodiment, the fastening section 20 of the glove 12 is designed as a strap section 56.

One end of the strap section 56 is connected in a fixed manner to the dorsal section 18 in the region of the trigger opening 30.

The other end of the strap section 56 can be fastened to the dorsal section 18, for example by means of the fastening elements 26, 28.

In the worn state, the strap section 56 is guided along the palm of the hand and runs through a further fastening opening 58 on the side of the dorsal section 18 facing away from the thumb. Then, the strap section 56 is guided along the palm of the hand once again and fastened coming across the thumb-side edge of the dorsal section 18 to the upper side O of the dorsal section 18, for example by means of the fastening elements 26, 28.

Only one size of glove 12 is required by this type of glove 12 as the glove 12 can be fixed in place on any size of hand securely and reliably as a result of the strap section 56.

1. A glove comprising a dorsal section and a fastening section,
wherein the fastening section is designed to fasten the dorsal section onto a user's hand,
wherein the dorsal section comprises a trigger opening and a holder opening, and
wherein the dorsal section is designed in such a way that a trigger of an electrical assembly can be inserted into the trigger opening and can be held there by at least one of the dorsal section or a holder of the electrical assembly can be inserted into the holder opening and can be held there by the dorsal section.

2. The glove according to claim 1, wherein the dorsal section is designed in such a way that at least one of the trigger or the holder can be inserted into the trigger opening or the holder opening, respectively, from an underside of the dorsal section.

3. The glove according to claim 1, wherein the dorsal section is free of at least one of conductors or rigid components.

4. The glove according to claim 1, wherein the dorsal section is designed flexibly.

5. The glove according to claim 1, wherein at least one of the trigger opening or the holder opening are limited by an edge of the dorsal section, wherein at least a fastening means for at least one of the trigger or for the holder is located on the edge.

6. The glove according to claim 1, wherein the fastening section is a palm section.

7. The glove according to claim 1, wherein the fastening section is a strap section.

8. A wearable device comprising a glove and an electrical assembly,
wherein the glove comprises a dorsal section and a fastening section, wherein the fastening section is designed to fasten the dorsal section onto a user's hand, wherein the dorsal section comprises a trigger opening and a holder opening, and wherein the dorsal section is designed in such a way that a trigger of an electrical assembly can be inserted into the trigger opening and can be held there by at least one of the dorsal section or a holder of the electrical assembly can be inserted into the holder opening and can be held there by the dorsal section,
wherein the electrical assembly comprises a trigger and a holder, which are connected electrically to each other by means of an electrical conductor,
wherein at least one of the trigger or the holder are inserted into the trigger opening or the holder opening, respectively, and are held by the dorsal section.

9. The device according to claim 8, wherein at least one of the trigger or the holder at least one of extend from an underside of the dorsal section through the trigger opening or the holder opening, respectively, or project over an upper side of the dorsal section.

10. The device according to claim 8, wherein at least one of the trigger the or holder have a size in at least one of a transverse direction or a longitudinal direction, wherein at least one of the trigger or the holder are larger in at least one of the longitudinal direction or the transverse direction as at least one of the trigger opening or holder opening in the corresponding direction.

11. The device according to claim 8, wherein the electrical assembly comprises a base layer, on which at least one of the trigger or the holder is attached.

12. The device according to claim 11, wherein the base layer adjoins an underside of the dorsal section.

13. The device according to claim 11, wherein the base layer has at least one fastening means.

14. The device according to claim 8, wherein the electrical assembly has a connecting part that extends from the holder to the trigger and defines a spacing between the trigger and the holder.

15. The device according to claim 8, wherein the electrical assembly comprises a connecting part that extends from the holder to the trigger and whose length is changeable in such a way that a spacing between the trigger and the holder is changeable.

16. The device according to claim 8, wherein the wearable device has an electronic module that is inserted into the holder.

17. The device according to claim 8, wherein the holder comprises at least one electrical contact that is connected electrically to the trigger by means of the conductor.

18. An electrical assembly for a wearable device comprising a trigger and a holder that are connected electrically to each other by means of an electrical conductor.

19. The electrical assembly according to claim 18, wherein the wearable device comprises a glove and an electrical assembly,
the glove comprising a dorsal section and a fastening section, wherein the fastening section is designed to fasten the dorsal section onto a user's hand, wherein the dorsal section comprises a trigger opening and a holder opening, and wherein the dorsal section is designed in such a way that a trigger of an electrical assembly can be inserted into the trigger opening and can be held there by at least one of the dorsal section or a holder of the electrical assembly can be inserted into the holder opening and can be held there by the dorsal section,
the electrical assembly comprising a trigger and a holder, which are connected electrically to each other by means of an electrical conductor, wherein at least one of the trigger or the holder are inserted into the trigger opening or the holder opening, respectively, and are held by the dorsal section.

20. The electrical assembly according to claim 18, wherein the electrical assembly has a connecting part that extends from the holder to the trigger and whose length is changeable in such a way that a spacing between the trigger and the holder is changeable.
